(19) United States
(12) Patent Application Publication
(10) Pub. No.: US 2014/0061578 A1
(43) Pub. Date: Mar. 6, 2014

(54) NONVOLATILE SEMICONDUCTOR MEMORY DEVICE

(71) Applicant: KABUSHIKI KAISHA TOSHIBA, Tokyo (JP)

(72) Inventors: Shigeki KOBAYASHI, Kuwana-shi (JP); Yasuhiro Nojiri, Yokohama-shi (JP); Masaki Yamato, Yokkaichi-shi (JP); Hiroyuki Fukumizu, Yokohama-shi (JP); Takeshi Yamaguchi, Yokkaichi-shi (JP)

(73) Assignee: Kabushiki Kaisha Toshiba, Tokyo (JP)

(21) Appl. No.: 13/780,734

(22) Filed: Feb. 28, 2013

Related U.S. Application Data
(60) Provisional application No. 61/695,661, filed on Aug. 31, 2012.

(51) Int. Cl. H01L 27/24

(52) U.S. Cl. CPC H01L 27/2481
USPC 257/5

(57) ABSTRACT

A nonvolatile semiconductor memory device below comprises: a memory cell array configured having memory cells arranged therein disposed at intersections of a plurality of first lines and a plurality of second lines formed so as to intersect each other, and the memory cells each comprising a variable resistance element; and a control circuit configured to select and drive the first lines and the second lines. The variable resistance element is configured by a transition metal oxide film. The variable resistance element is electrically connected to a first electrode configured from a metal at a first surface and is electrically connected to a second electrode at a second surface which is on an opposite side to the first surface. A first insulating film is formed between the first electrode and the variable resistance element. The first insulating film is formed by a first material that is formed by covalent binding.

### CROSS REFERENCE TO RELATED APPLICATIONS

This application is based on and claims the benefit of priority from prior Provisional U.S. Patent Application No. 61/695,661, filed on Aug. 31, 2012, the entire contents of which are incorporated herein by reference.

### FIELD

Embodiments described in this specification relate to a nonvolatile semiconductor memory device.

### BACKGROUND

Conventionally known and market-released semiconductor memory devices such as DRAM, SRAM, and flash memory have all use a MOSFET as a memory cell. Therefore, along with miniaturization of patterns, it has been required to improve dimensional accuracy at a rate exceeding the rate of miniaturization. As a result, a large burden has also been placed on lithography technology for forming these patterns, which has been a major cause of a rise in product costs.

In recent years, resistance change memory has been receiving attention as a successor candidate of such semiconductor memory devices employing a MOSFET as a memory cell. Such a resistance change memory has advantages that a cross-point type cell structure in which memory cells are formed at intersections of intersecting bit lines and word lines can be adopted, making miniaturization easy compared to conventional memory cells, and also a stacking the structures in the vertical direction to the wafer surface can simply increase the memory capacity.

A write operation (setting operation) of data to a resistance change memory of so-called bipolar type is performed by applying to a variable resistance element a setting voltage of a first polarity. This causes the variable resistance element to change from a high-resistance state to a low-resistance state. On the other hand, an erase operation (resetting operation) of data is performed by applying to a variable resistance element in a low-resistance state after a setting operation a resetting voltage of a second polarity which is opposite to the first polarity applied during the setting operation. This causes the variable resistance element to change from a low-resistance state to a high-resistance state.

As described above, in a bipolar type resistance change memory, the setting operation or the resetting operation are executed by applying voltages having opposite polarities to each other (setting voltage, resetting voltage). The memory cell needs a selector with which the applied bias and current are supplied to only the selected memory cells. For example, a diode can be used as the selector. Reduction of setting voltage and resetting voltage is beneficial in terms of low power consumption of the memory cells. In addition, reducing the setting voltage and resetting voltage can reduce the electrical stress to the selector in the non-selected memory cells. In the non-selected memory cells, the large portion of applied electrical bias is consumed at the selector, and electrical bias across the variable resistance element is too low to change the resistance values in the variable resistance element. Thus, reducing setting voltage and resetting voltage can decrease the bias which is needed to be consumed at the selector in the non-selected memory cells, and improve the reliability of the selector.

### BRIEF DESCRIPTION OF THE DRAWINGS

FIG. 1 is a schematic view of a nonvolatile semiconductor memory device according to an embodiment.

FIG. 2 is a perspective view showing a stacking structure 10A of a memory cell array 10.

FIG. 3 is a perspective view showing a stacking structure 10C of the memory cell array 10.

FIG. 4 is a cross-sectional view showing a configuration of a memory layer 60.

### DETAILED DESCRIPTION

A nonvolatile semiconductor memory device according to an embodiment below comprises: a memory cell array configured having memory cells arranged therein, the memory cells disposed at intersections of a plurality of first lines and a plurality of second lines that are formed so as to intersect each other, and the memory cells each comprising a variable resistance element; and a control circuit for selecting and driving the first lines and the second lines. The variable resistance element is configured by a metal oxide film. The variable resistance element is electrically connected to a first electrode configured from a metal at a first surface and is electrically connected to a second electrode at a second surface which is on an opposite side to the first surface. A first insulating film is formed between the first electrode and the variable resistance element, the first insulating film being formed by a first material that is formed by covalent binding.

Embodiments of the present invention are exemplified below with reference to the drawings. Note that in each of the drawings, similar configurative elements are assigned with identical reference symbols, and detailed descriptions of such elements are appropriately omitted. Moreover, arrow X, arrow Y, and arrow Z in the drawings indicate directions that are orthogonal to each other.

[Outline]

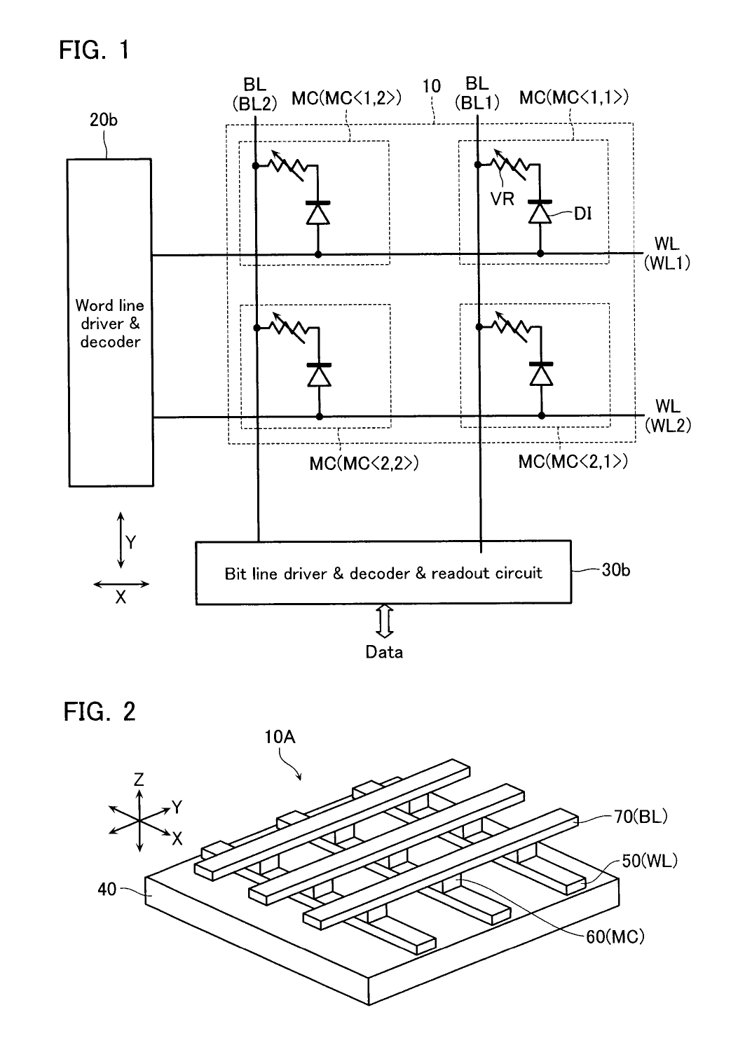

First, an outline of the nonvolatile semiconductor memory device according to the embodiment is described with reference to FIG. 1. FIG. 1 is a schematic view of the nonvolatile semiconductor memory device according to the embodiment.

As shown in FIG. 1, the nonvolatile semiconductor memory device according to the embodiment includes a memory cell array 10, a word line drive circuit 20b, and a bit line drive circuit 30b.

The memory cell array 10 includes word lines WL (WL1 and WL2) and bit lines BL (BL1 and BL2) that intersect each other, and memory cells MC (MC<1,1>˜MC<2,2>) disposed at intersections of the word lines WL and the bit lines BL.

The word lines WL are arranged with a certain pitch in the Y direction and formed extending in the X direction. The bit lines BL are arranged with a certain pitch in the X direction and formed extending in the Y direction. The memory cells MC (MC<1,1>˜MC<2,2>) are disposed in a matrix on a surface formed in the X direction and the Y direction.

The memory cell MC includes a diode DI and a variable resistance element VR connected in series. The diode DI functions as a selection element for allowing a desired current to flow only in a selected memory cell MC.

The variable resistance element VR can be repeatedly changed between a low-resistance state and a high-resistance state by application of a voltage or supply of a current. The memory cell MC stores data in a nonvolatile manner based on a resistance value of these two states. One side of the diode DI is connected electrically to the word line WL, and the other side of the diode DI is connected electrically to one end of the variable resistance element VR. The other end of the variable resistance element VR is connected electrically to the bit line BL.

The word line drive circuit 20b applies to the word line WL a voltage required for erase of data stored in the memory cell MC, write of data to the memory cell MC, and read of data from the memory cell MC. Moreover, the word line drive circuit 20b supplies to the word line WL a current required in erase of data, write of data, and read of data.

The bit line drive circuit 30b applies to the bit line BL a voltage required for erase of data stored in the memory cell MC, write of data to the memory cell MC, and read of data from the memory cell MC. Moreover, the bit line drive circuit 30b supplies to the bit line BL a current required in erase of data, write of data, and read of data. In addition, the bit line drive circuit 30b outputs data read via the bit line BL to external.

[Stacking Structure]

Next, a stacking structure of the memory cell array 10 is described with reference to FIGS. 2˜3. FIGS. 2˜3 are schematic perspective views showing stacking structures of the memory cell array 10.

The memory cell array 10 is configured by a stacking structure 10A shown in FIG. 2. The stacking structure 10A includes, stacked in a Z direction on a surface of a substrate 40 from a lower layer to an upper layer, a first conductive layer 50, a memory layer 60, and a second conductive layer 70. The first conductive layer 50 herein functions as the previously mentioned word line WL.

The memory layer 60 functions as the previously mentioned memory cell MC. The second conductive layer 70 functions as the previously mentioned bit line BL. That is, the stacking structure 10A (memory cell array 10) has a so-called cross-point type configuration where the memory layer 60 (memory cell MC) is disposed at an intersection of the first conductive layer 50 (word line WL) and the second conductive layer 70 (bit line BL).

The first conductive layer 50 is formed in stripes extending in the X direction with a certain pitch in the Y direction. The first conductive layer 50 is formed from a conductive material (for example, a metal or conductive poly-silicon which has impurities inside). The first conductive layer 50 is desirably formed from a material of high heat resistance and having a low resistance value. Examples of the material may include the likes of tungsten (W), titanium (Ti), tantalum (Ta), and their nitrides, or stacked arrangements of these metals and nitrides, or poly-silicon having phosphorus(P), arsenic(As), or Boron(B).

The memory layer 60 is provided on the first conductive layer 50, and is disposed in a matrix in the X direction and the Y direction.

The second conductive layer 70 is formed in stripes extending in the Y direction with a certain pitch in the X direction. The second conductive layer 70 is formed to contact an upper surface of the memory layer 60. The second conductive layer 70 is desirably formed from a material of high heat resistance and having a low resistance value. Examples of the material may include the likes of tungsten (W), titanium (Ti), tantalum (Ta), and their nitrides, or stacked arrangements of these metals and nitrides, or poly-silicon having phosphorus(P), arsenic(As), or Boron(B). Note that the first conductive layer 50 and the second conductive layer 70 may be formed from the same material or may be formed from different materials.

The stacking structure 10A exemplified in FIG. 2 includes a single first conductive layer 50, a single memory layer 60, and a single second conductive layer 70. That is, when the memory cell array is formed along multiple layers, these first conductive layer 50, memory layer 60, and second conductive layer 70 are formed alternately. However, the memory cell array 10 is not limited to the stacking structure 10A.

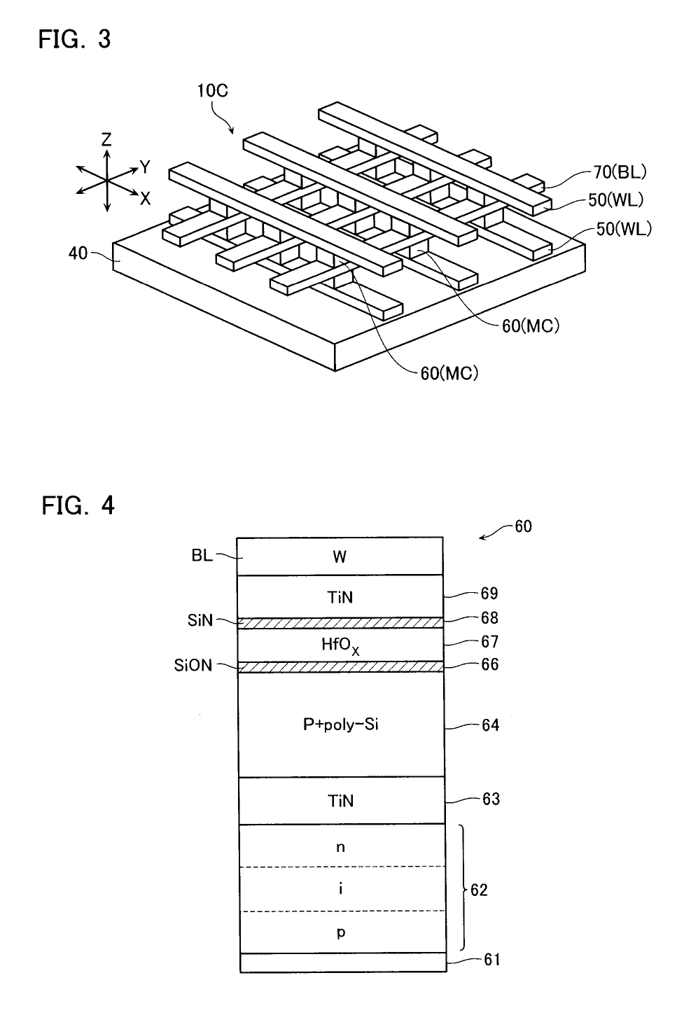

Moreover, the memory cell array 10 may be configured by a stacking structure 10C shown in FIG. 3. The stacking structure 10C includes a memory layer 60 formed in a layer above the second conductive layer 70 of the stacking structure 10A (in the Z direction) and a first conductive layer 50 formed in a layer above this memory layer 60 (in the Z direction). That is, in the stacking structure 10C, upper and lower memory layers 60 share the second conductive layer 70 disposed between them.

Description of the present embodiment proceeds assuming the memory cell array 10 to have the structure of FIG. 2.

[Memory Layer 60]

Next, a configuration of the memory layer 60 is described. FIG. 4 is a cross-sectional view showing the configuration of the memory layer 60 in the embodiment.

The memory layer shown in FIG. 4 comprises, sequentially from a lower layer to an upper layer, an electrode layer 61, a diode layer 62, an electrode layer 63, a polysilicon layer 64, a silicon oxide-nitride film 66, a variable resistance layer 67, an insulating film 68, and an electrode layer 69. The previously mentioned diode DI is formed by the diode layer 62, and the previously mentioned variable resistance element VR is formed by the variable resistance layer 67.

The electrode layer 61 is formed by for example titanium nitride (TiN). The diode layer 62 is formed in a layer above the electrode layer 61. Adoptable as the diode layer 61 is for example a diode layer having a MIM (Metal-Insulator-Metal) structure or a PIN (P-type polysilicon-Intrinsic-N-type polysilicon) structure.

The electrode layer 63 is formed in a layer above the diode layer 62. Similarly to the electrode layer 61, the electrode layer 63 may be formed by titanium nitride (TiN). The electrode layer 61 and the electrode layer 63 may be formed from at least one kind of metal selected from “element group g1” shown below or any of nitrides and carbides of “element group g1” such as those in “compound group g1” shown below. Alternatively, the electrodes 61 and 63 may be formed from a composite body of these. The electrode layer 69 may also similarly be formed by titanium nitride.

element group g1: tungsten (W), tantalum (Ta), hafnium (Hf), silicon (Si), iridium (Ir), rubidium (Ru), gold (Au), platinum (Pt), palladium (Pd), molybdenum (Mo), nickel (Ni), chromium (Cr), cobalt (Co), and titanium (Ti)

compound group g1: Ti—N, Ti—Si—N, Ta—N, Ta—Si—N, Ti—C, Ta—C, Hf—N and W-N

Note that the electrode layer 69 preferably has a work function of 4.5 eV or more from the viewpoint of lowering a setting voltage Vset.

The polysilicon layer 64 is formed in a layer above the electrode layer 63, and functions as an electrode electrically connected to the variable resistance layer 67. In this example, the polysilicon layer 64 is configured by polysilicon of P+ type. The variable resistance layer 67 is formed in a layer above this polysilicon layer 64 via the silicon oxide-nitride film 66. The silicon oxide-nitride film 66 has a film thickness of for example about 1.5 nm.

The variable resistance layer 67 is formed by a metal oxide. The metal is for example hafnium (Hf), manganese (Mn), zirconium (Zr), tungsten (W), titanium (Ti), tantalum(Ta), or aluminum(Al). Description proceeds here illustrating an example where hafnium is selected. However, it is clear from the description below that similar advantages may also be expected when other transition metals are employed. The transition metal oxide is formed by ion binding.

The insulating film 68 is formed by an insulator that is formed by covalent binding. As an example, the insulating film 68 is formed from an insulating film having covalent binding of silicon (Si) and nitrogen (N), for example, silicon nitride (SiN), and has a film thickness of about 0.5˜3 nm. This insulating film 68 is inserted to make it easy for ion binding of HfOx ion-bound in the variable resistance layer 67 to be severed. Promoting severance of ion binding has an advantage of lowering the setting voltage Vset required during a setting operation. It is also possible to form the insulating film 68 by for example silicon oxide (SiO2) or SiON, as well as by silicon nitride.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a memory cell array configured having memory cells arranged therein, the memory cells disposed at intersections of a plurality of first lines and a plurality of second lines that are formed so as to intersect each other, and the memory cells each comprising a variable resistance element; and
a control circuit configured to select and drive the first lines and the second lines,
the variable resistance element being configured by a transition metal oxide film,
the variable resistance element being electrically connected to a first electrode configured from a metal at a first surface and being electrically connected to a second electrode at a second surface which is on an opposite side to the first surface, and
a first insulating film being formed between the first electrode and the variable resistance element, the first insulating film being formed by a first material that is formed by covalent binding.

2. The nonvolatile semiconductor memory device according to claim 1, wherein
the first insulating film has covalent binding of silicon (Si) and nitrogen (N).

3. The nonvolatile semiconductor memory device according to claim 2, wherein
a film thickness of the first insulating film is 0.5 to 3 nm.

4. The nonvolatile semiconductor memory device according to claim 3, wherein
the first electrode includes titanium nitride (TiN).

5. The nonvolatile semiconductor memory device according to claim 4, wherein
the second electrode includes polysilicon.

6. The nonvolatile semiconductor memory device according to claim 1, wherein
the variable resistance element is formed by ion binding.

7. The nonvolatile semiconductor memory device according to claim 6, wherein
the first insulating film has covalent binding of silicon (Si) and nitrogen (N).

8. The nonvolatile semiconductor memory device according to claim 7, wherein
a film thickness of the first insulating film is 0.5 to 3 nm.

9. The nonvolatile semiconductor memory device according to claim 8, wherein
the first electrode includes titanium nitride (TiN).

10. The nonvolatile semiconductor memory device according to claim 9, wherein
the second electrode includes polysilicon.

11. The nonvolatile semiconductor memory device according to claim 1, wherein
the variable resistance element is formed by hafnium oxide.

12. The nonvolatile semiconductor memory device according to claim 11, wherein
the first insulating film has covalent binding of silicon (Si) and nitrogen (N).

13. The nonvolatile semiconductor memory device according to claim 12, wherein
a film thickness of the first insulating film is 0.5 to 3 nm.

14. The nonvolatile semiconductor memory device according to claim 13, wherein
the first electrode includes titanium nitride (TiN).

15. The nonvolatile semiconductor memory device according to claim 14, wherein
the second electrode includes polysilicon.
